(19) United States
(12) Patent Application Publication
(10) Pub. No.: US 2026/0177933 A1
(43) Pub. Date: Jun. 25, 2026

(54) METROLOGY DEVICE NORMALIZATION CHANNEL

(71) Applicant: Onto Innovation Inc., Wilmington, MA (US)

(72) Inventors: Tuwin LAM, Santa Clara, CA (US); Lawrence ROTTER, Pleasanton, CA (US); Mikhail HAURYLAU, San Jose, CA (US); Shukai YU, Tampa, FL (US)

(73) Assignee: Onto Innovation Inc., Wilmington, MA (US)

(21) Appl. No.: 18/991,234

(22) Filed: Dec. 20, 2024

(51) Int. Cl. G03F 7/00

(52) U.S. Cl. CPC G03F 7/706837; G03F 7/706831; G03F 7/706851

(57) ABSTRACT

Optical metrology is performed using a light source and a normalization channel. A portion of the light is directed to the normalization channel, which detects the intensity of the light while measurements are acquired from the light reflected from a sample. The measurements are normalized based on the detected intensity of the light in the normalization channel. The light detected in the normalization channel may be synchronized with the measurements. Moreover, the acquisition of the intensity of the light in the normalization channel may be aligned with the measurements. The normalization channel measurements may be a single total intensity value that is applied to all wavelengths in the measurements, or may be a function of wavelength that is applied to the corresponding wavelengths in the spectral measurements.

### FIELD OF THE DISCLOSURE

The subject matter described herein is related generally to optical metrology, and more particularly to systems and processes for reducing noise in optical metrology measurements.

### BACKGROUND

Semiconductor and other similar industries often use optical metrology equipment to provide non-contact evaluation of samples during processing. Examples of optical metrology include reflectometry, ellipsometry, interferometry, scatterometry, etc. With optical metrology, a sample under test is illuminated with light, e.g., at a single wavelength or multiple wavelengths. The light interacts with the sample and the resulting light is detected by one or more photosensitive elements, such as a photodetector or photodetector array, charge coupled device (CCD) array, complementary metal-oxide-semiconductor (CMOS) sensor, etc. The detected light is analyzed from which one or more physical properties of the sample may be determined.

Optical metrology is capable of measuring various sample parameters with a high degree of precision. However, optical metrology is extremely sensitive to various sources of noise, such as vibration, stray light, etc. One source of noise is found in the light source. For example, even high quality light sources may fluctuate in intensity by small amounts, which may adversely affect the data acquired by the optical metrology device and, consequently, impact the precision of measurements.

### SUMMARY

Optical metrology is performed using a normalization channel to mitigate, e.g., reduce or eliminate, the noise produced in the light source. A portion of the light produced by the light source is directed to the normalization channel that detects the intensity of the light while measurements are acquired from the light reflected from a sample. The measurements are normalized based on the detected intensity of the light in the normalization channel. The light detected in the normalization channel may be synchronized with the measurements. Moreover, the light detected in the normalization channel may be aligned with the measurements. The measurements may be spectral measurements and the normalization channel data may be a single total intensity value that is applied to all wavelengths in the spectral measurements or may be spectral data that is applied to the corresponding wavelengths in the spectral measurements.

In some implementations, a method of performing optical metrology that mitigates light source noise using a normalization channel includes generating light with a light source having fluctuations in light intensity and directing a portion of the light to a normalization channel. Measurements are acquired from light reflected from a sample and the light intensity of the light is detected in the normalization channel while acquiring the measurements. The method includes normalizing the measurements based on the light intensity detected in the normalization channel.

In some implementations, a metrology device configured for performing optical metrology that mitigates light source noise using a normalization channel includes a light source generating light having fluctuations in light intensity and a beam splitter that directs a portion of the light to a normalization channel. The metrology device includes a detector configured to acquire measurements from light reflected from a sample and a normalization channel configured to detect the light intensity of the light while acquiring the measurements. The metrology device includes a computing system configured for normalizing the measurements based on the light intensity detected in the normalization channel.

### BRIEF DESCRIPTION OF THE DRAWINGS

FIGS. 1A and 1B illustrate schematic view of a normal and oblique incidence metrology device configured with a normalization channel, as described herein.

FIG. 2 illustrates a high level flow of data acquisition performed by a metrology device with a normalization channel, as described herein.

FIG. 3 illustrates a timing diagram showing an example of synchronization and alignment between the detector and the normalization channel during measurement and normalization data acquisition.

FIG. 4 illustrates a graph showing saturation of the normalization channel.

FIG. 5 illustrates a graph showing application of gain switching to avoid saturation of the normalization channel.

FIG. 6 illustrates a flowchart depicting an example method for performing optical metrology with a normalization channel, as discussed herein.

### DETAILED DESCRIPTION

During fabrication of semiconductor devices and similar devices it is often necessary to monitor the fabrication process by non-destructively measuring the devices. Optical metrology techniques, such as reflectometry, ellipsometry, interferometry, scatterometry, etc., are often employed for non-contact evaluation of samples during processing. Optical metrology is advantageous as it enables non-contact measurements that are accurate and precise. A high degree of precision is important for repeatability and reproducibility of measurements. For example, not only is it desirable for measurements to be repeatable over an extended period of time, e.g., from measurement site to measurement site, or from wafer to wafer, but it is desirable for measurements to be repeatable over the reference interval, i.e., in the time periods between collecting reference data.

Optical metrology devices, however, are typically sensitive to various sources of noise, which may affect precision or repeatability. One source of noise is from the light source, which is sometimes referred to as lamp noise. The light source, for example, may produce small fluctuations in the intensity of the light produced, which may result in a lack of repeatability. By way of example, during measurement, data is typically collected from both the sample and a reference sample. The reference sample, for example, is a structure with well calibrated physical parameters, e.g., the composition and thicknesses of the materials are known. The data collected from the sample is compared to the data collected from the reference sample during the analysis to determine one or more physical properties of the sample. By way of example, for spectroscopic reflectometer measurements, the basic equation to calculate the reflectivity (Rₛₐₘ(λ)) of a sample is:

$${R}_{sam} ( λ ) = \frac{{I}_{sam} ( λ ) - {I}_{dark} ( λ )}{{I}_{ref} ( λ ) - {I}_{dark} ( λ )} {R}_{ref} ( λ ) \qquad eq . 1$$

Where λ is wavelength; Iₛₐₘ(λ) and I_{ref}(λ) are the spectroscopic intensity signals measured for the sample and reference, respectively; I_{dark}(λ) is the dark signal or background signal, i.e., without presence of a sample or shutter closed; and R_{ref}(λ) is the reflectivity of the reference, which may be calculated from theory and tabulated optical constants.

The reference data, i.e., I_{ref}(λ) in equation 1, is collected periodically, e.g., at predefined intervals sometimes referred to as a reference interval, to account for a drift in the intensity of the light source over time. The reference data, for example, may be collected by the optical metrology device every hour, or at shorter or longer reference intervals. The analysis of sample data collected within a reference interval, e.g., as illustrated in equation 1, is based on an assumption that the intensity of the light source remains constant between the time of collecting the reference data and the time of collecting the sample data. This assumption, however, is not necessarily true. The light source may fluctuate in intensity during the reference interval. Any fluctuations in light source intensity that occur within a reference interval, i.e., between reference data collection, will impact the analysis of the sample data, e.g., the calculated reflectivity illustrated in equation 1, and thus will degrade the measurement precision and repeatability.

As discussed herein, a normalization channel may be included in the optical metrology device to monitor fluctuations of the intensity of the light source while collecting data. The normalization channel, for example, receives a portion of the light during data acquisition and one or more photodetectors in the normalization channel detect the intensity of the light. The detected intensity from the normalization channel may be used to normalize the sample data measurements.

By way of example, the spectroscopic reflectometer measurements from equation 1 to calculate the normalized reflectivity (Rₛₐₘ,norm (λ)) of a sample may be corrected using a normalization channel as:

$${R}_{sam , norm} ( λ ) = \frac{( {I}_{sam} ( λ ) - {I}_{dark} ( λ ) ) / ( {N}_{sam} - {N}_{dark} )}{( {I}_{ref} ( λ ) - {I}_{dark} ( λ ) ) / ( {N}_{ref} - {N}_{dark} )} {R}_{ref} ( λ ) \qquad eq . 2$$

Where Nₛₐₘ and N_{ref} are the intensity signals measured for the sample and reference from the normalization channel at the time of collecting Iₛₐₘ (λ) and I_{ref}(λ), respectively; and N_{dark} is the dark signal from the normalization channel. The intensity signal from the normalization channel, e.g., Nₛₐₘ, N_{ref}, and N_{dark}, may be the total intensity of light source, i.e., over wavelength range of the light source, so that a constant correction is applied to all light source wavelengths. In this implementation, for example, a photodetector may be used in the normalization channel to collect the light over all wavelengths. This implementation is based on the presumption that the intensity variation at each wavelength from the light source is highly correlated to the total intensity variation. If desired, however, in some implementations, the intensity signal produced by the normalization channel may be a spectral signal, e.g., Nₛₐₘ (λ), N_{ref} (λ), and N_{dark} (λ), so that the applied correction may be a function of wavelength or group of wavelengths. In one implementation, for example, a spectrometer may be used in the normalization channel to collect the light for each wavelength or for multiple groups of wavelengths. In one implementation, a photodetector may be used in the normalization channel to collect a total intensity value for the light over all wavelengths, and a spectral normalization signal may be generated based on the total intensity value and wavelength dependent weighting factors. The normalization data acquired by the normalization channel may be synchronized with the detected measurement data. Moreover, the detected normalization data may be aligned with the detected measurement data, e.g., so that the normalization data is acquired during the same window of time as the measurement data.

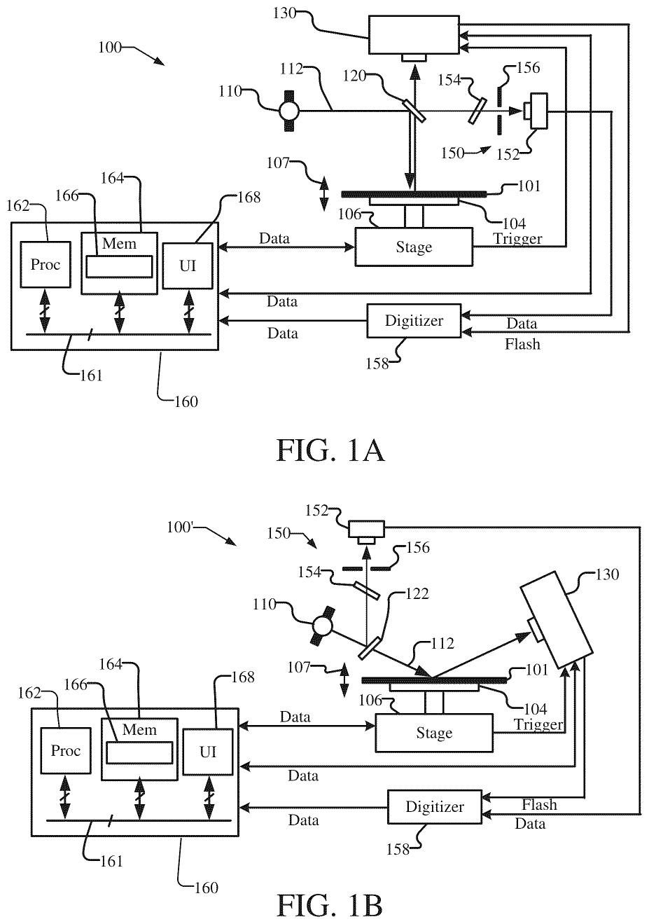

FIG. 1A, by way of example, illustrates schematic view of a metrology device 100 configured with a normalization channel 150, as described herein. The normalization channel monitors and mitigates, e.g., reduces or eliminates, the impact of fluctuations of the intensity of the light source while collecting data to improve the repeatability of measurements, e.g., over a time scale that is less than the reference interval. FIG. 1A illustrates a schematic view of a metrology device 100 that operates at normal incidence, such as a spectroscopic reflectometer, but if desired, may be another type of normal incidence metrology device.

The metrology device 100 includes a light source 110 that produces light 112 that may have multiple wavelengths (multi-λ). For example, the light source 110 may be a broadband light source, such as a Xenon or Tungsten Halogen light source, that produces broadband light and one or more wavelength separators. In some implementations, the light source 110 may include a plurality of separate sources, such as a plurality of lasers or a plurality of light emitting diode (LED) s (or any combination thereof) that each produce a beam with a different wavelength of light that are combined into light 112 that is colinear along the same optical axis. In some implementations, the light source 110 may be a monochromatic light source that produces light 112 with a narrow band of wavelengths. While the present disclosure sometimes refers to broadband light and spectral measurements, it should be understood that the normalization channel may be used with a single wavelength or narrow band wavelength system.

A portion of the light 112 is directed towards a sample 101 by a beam splitter 120. The light that is incident on the sample 101 interacts with and is reflected by the sample 101, and the beam splitter 120 directs at least a portion of the reflected light to a detector 130. The detector 130, for example, may be a photodetector, a detector array, or a spectrometer that detects the light intensity as a function of wavelength of the broadband light to acquire spectral measurements from the sample.

It should be understood that additional optical elements may be included in the optical path of the light 112 that is incident on and reflected by the sample 101 and received by the detector 130. For example, the optical path of the light 112 may include optical elements such as one or more lenses, e.g., refractive or reflective lenses; beam conditioning or shaping optical elements, such as field stops and apertures; polarizing elements; modulating elements, such as a rotating compensator or waveplate, photoelastic modulator (PEM), an acousto-optic modulator (AOM), an electro-optic modulator (EOM), etc.

The sample 101 is held on a chuck 104 and is positioned with a stage 106 that includes one or more actuators, e.g., to control the Z height of the sample 101, illustrated by arrows 107, as well as aligns desired measurement locations on the sample 101 with the optical path of the light 112. In some implementations, one or more optical components, e.g., light source 110, beam splitter 120, detector 130, etc., may move in one or more directions relative to the sample 101 to control the relative position and orientation of the sample 101 during measurement. The stage 106 may produce an output signal (referred to herein as stage trigger) to the detector 130 to initiate data acquisition. In some implementations, the stage trigger may be provided from the stage 106 directly to the detector 130 and in some implementations, the stage trigger may be provided via an intermediate component, while in other implementations, the stage trigger may be generated by a separate component, e.g., computing system 160.

The normalization channel 150 receives a portion of the light 112 from the beam splitter 120. For example, in the normal incidence configuration, illustrated in FIG. 1A, the normalization channel 150 receives a portion of the light 112 transmitted through the existing beam splitter 120, which is conventionally treated as waste light and captured by a beam dump. By using the portion of the light 112 transmitted by beam splitter 120, the normalization channel 150 uses existing light and therefore there is no light loss in the spectrometer signal from the detector 130.

The normalization channel 150 includes a normalization detector 152 that receives the light 112 while the detector 130 acquires the measurements from the sample 101. The normalization detector 152, for example, may be a photodetector that indicates the total intensity of the light source 110. The use of a single correction for all wavelengths, allows the normalization detector 152 to be a relatively simple photodetector and avoids the use of a second spectrometer, i.e., that is in addition to the spectrometer in the detector 130. The normalization detector 152, for example, may be a single channel Si photodiode or Si PIN photodiode with a sufficiently fast response time. The photodetector should have a sufficient responsivity in a desired wavelength range with respect to its Noise Equivalent Power (NEP) to achieve a desired shot noise specification. By way of example, it can be a Thorlabs PDAPC2, Hamamastu S1337-1010BQ, or other similar photodetector. In some implementations, the normalization detector 152 may be a spectrometer, which may indicate the intensity per wavelength.

The normalization channel 150 may further include an optical bandpass filter 154, which may pass wavelengths in a range suitable for the normalization detector 152, e.g., within the temperature coefficient of responsivity (TCR). The normalization channel 150 may further include an aperture stop 156 to block scattered light and selected so that the beam reaching the normalization detector 152 matches the beam reaching the detector 130. To minimize ghosts to the detector 130 and, e.g., pattern recognition camera, if present, flat reflecting surfaces within the normalization channel 150, such as filter 154 and detector 152 may be tilted with respect to the incoming beam.

The normalization channel 150 may further include a digitizer 158 that is coupled between the normalization detector 152 and at least one computing system 160. The digitizer 158, for example, may receive normalization data, e.g., the detected light intensity signals from the normalization detector 152, digitize the signals and provide the signals to the computing system 160. Additionally, the digitizer 158 may receive an output pulse (referred to herein as a flash) from the detector 130 for synchronizing the normalization channel 150 with the detector 130. In some implementations, the flash may be provided from the detector 130 directly to the digitizer 158 and in some implementations, the flash may be provided via an intermediate component, e.g., a Peripheral Component Interconnect Express (PCIE) card in the computing system 160.

FIG. 1B, by way of example, illustrates a schematic view of a metrology device 100′ configured with a normalization channel 150, as described herein. Metrology device 100′ is similar to metrology device 100, illustrated in FIG. 1A, like designated elements being the same. FIG. 1B, however, illustrates metrology device 100′ operating at oblique incidence, as opposed to normal incidence as illustrated in FIG. 1A. Metrology device 100′, for example, may be a spectroscopic ellipsometer, or other oblique incidence metrology device.

It should be understood that metrology device 100′ may include additional optical elements in the optical path of the light 112. For example, if metrology device 100′ operates as an ellipsometer, a polarization state generator is positioned in the optical path before the sample 101 and a polarization state analyzer is positioned in the optical path after the sample 101. The polarization state generator and polarization state analyzer, for example, include polarizers and one or more rotating compensators or waveplates.

Additionally, with the oblique incidence configuration shown in FIG. 1B, the beam splitter 120 shown in FIG. 1A is not necessary. Accordingly, a beam splitter 122 is added to the optical path of the light 112 to direct a portion of the light 112 to the normalization channel 150. FIG. 1B illustrates the beam splitter 122 positioned before the sample 101, i.e., between the light source 110 and the sample 101. For example, the beam splitter 122 may be positioned before the polarization state generator, if the metrology device 100′ operates as an ellipsometer. If desired, however, the beam splitter 122 may be positioned after the sample 101, i.e., between the sample 101 and the detector 130.

Regardless of configuration, the metrology device 100 and metrology device 100′, sometimes collectively referred to herein as metrology device 100, include at least one computing system 160 that is coupled to the detector 130 to receive measurement data acquired by the detector 130. The computing system 160 is further coupled to the normalization detector 152, via the digitizer 158, to receive normalization data acquired by the normalization detector 152. The computing system 160 is further coupled to the stage 106 to control the operation of the stage 106, e.g., to control the chuck 104 and movement of the stage 106 to control the position and orientation of the sample 101 during measurement. The computing system 160 may be further configured to receive data and provide control signals from and to the detector 130, normalization detector 152, and stage 106 to trigger operation and acquisition of the measurement data and the normalization data, as discussed herein. The computing system 160 may be further configured to control and monitor other aspects of the operation of the metrology device 100, including the light source 110 and other optical components, such as any polarization state generator and polarization state analyzer or rotating elements that may be present in the optical path. The computing system 160 may be further configured to normalize the sample measurements based on the acquired measurement data and acquired normalization data and to determine one or more physical properties of the sample. For example, the computing system 160 may be configured to perform the measurements illustrated in equation 2. The computing system 160 may be configured to control and acquire data from various one or more subsystems of the metrology device 100, e.g., by a transmission medium that may include wireline and/or wireless portions. The transmission medium, thus, may serve as a data link between the computing system 160 and other subsystems of the metrology device 100.

The at least one computing system 160, for example, may be a workstation, a personal computer, central processing unit or other adequate computer system, or multiple systems. It should be understood that the at least one computing system 160 may be a single computer system or multiple separate or linked computer systems, including one or more processors which may be coupled to one or more computational nodes (blades), which may be interchangeably referred to herein as computing system 160, at least one computing system 160, one or more computing systems 160, etc. In some implementations, the computing system 160 or components of the computing system 160 may be separate from the metrology device 100 while in some implementations, the computing system 160 may be included in or is connected to or otherwise associated with metrology device 100. Additionally, different subsystems of the metrology device 100 may each include a computing system that is configured for carrying out steps associated with the associated subsystem. For example, the at least one computing system 160 may be coupled to separate computing systems associated with the detector 130, normalization detector 152, and stage 106.

The computing system 160 includes at least one processor 162 with memory 164, as well as a user interface (UI) 168, which are communicatively coupled via a bus 161. The memory 164 or other non-transitory computer-usable storage medium, includes computer-readable program code 166 embodied thereof and may be used by the computing system 160 for causing the at least one computing system 160 to control the metrology device 100 and/or to perform functions including encoding the angular distribution of the incident light, as described herein. The data structures and software code for automatically implementing one or more acts described in this detailed description can be implemented by one of ordinary skill in the art in light of the present disclosure and stored, e.g., on a computer-usable storage medium, e.g., memory 164, which may be any device or medium that can store code and/or data for use by a computer system, such as the computing system 160. The computer-usable storage medium may be, but is not limited to, include read-only memory, a random access memory, magnetic and optical storage devices such as disk drives, magnetic tape, etc. Additionally, the functions described herein may be embodied in whole or in part within the circuitry of an application specific integrated circuit (ASIC) or a programmable logic device (PLD), and the functions may be embodied in a computer understandable descriptor language which may be used to create an ASIC or PLD that operates as herein described.

The computing system 160 may be configured to determine one or more characteristics of the sample 101 based on data acquired by detector 130 and normalization detector 152. By way of example, the computing system 160 may determine one or more characteristics of the sample 101 using known reflectometry, ellipsometry and other metrology techniques, that are modified based on the normalization channel 150, as discussed herein. The results from the analysis may be stored, e.g., in memory 164 associated with the sample and/or provided to a user, e.g., via the UI 168. In some implementations, the results of the analysis may be provided, e.g., via a port, to other metrology systems to assist with additional measurements or inspection or fed back or fed forward to processing systems for adjusting processing steps in response to the analysis.

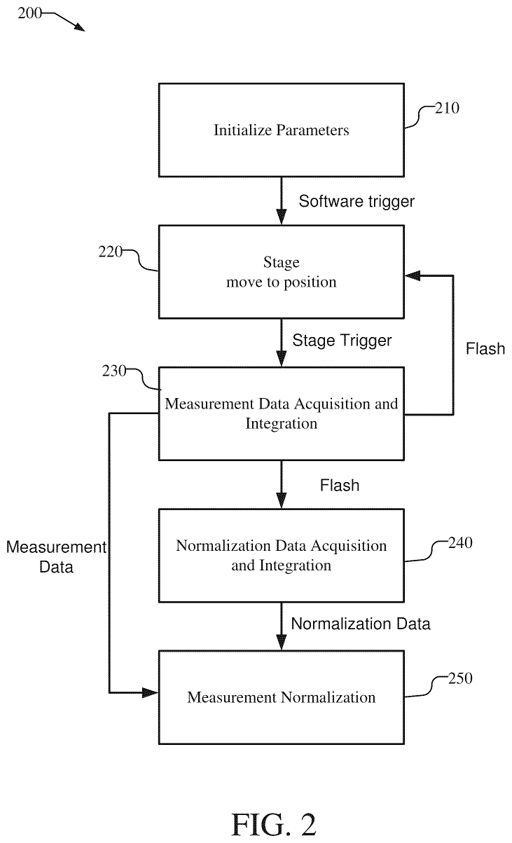

FIG. 2 illustrates a high level flow 200 of the data acquisition performed by metrology devices 100 and 100′ shown in FIGS. 1A and 1B. The data acquisition flow 200 shown in FIG. 2 may be used to acquire data for reflectivity measurements, as illustrated in equation 2, or any other desired optical metrology measurements. The data acquisition in the normalization channel 150, in some implementations, may rely on an output pulse (flash) from the detector 130 to synchronize acquisition of the normalization data with the acquisition of the measurements. The detector 130, for example, may send a flash to the digitizer 158 at every end of scan (EOS), at the end of a scan read out, or at a predetermined time after starting a scan. The flash may be sent by the detector 130 to the digitizer 158 directly or via an intervening component, such as through a PCIE board in the computing system 160. The digitizer 158 may start the integration time for the normalization channel in response to receipt of the flash, thereby synchronizing acquisition of the normalization data with the acquisition of the measurements from detector 130. In some implementations, the digitizer 158 may start the integration time after a predetermined phase delay after receipt of the flash in order to align the time of acquisition of the normalization data with the time of acquisition of the measurements from the detector 130. The total number of scans may be set before the integration by the digitizer 158. In an implementation in which the normalization detector 152 is a photodetector, a single data value is generated by the normalization detector 152 and digitizer 158 after each flash trigger. In an implementation in which the normalization detector 152 is a spectrometer, a spectrum is generated by the normalization detector 152 and digitizer 158 after each flash trigger. The integration time for the normalization channel is equal to the integration time of detector 130. FIG. 2 illustrates one example of the measurement sequence for acquisition of the normalization data.

At block 210, the computing system 160 initializes the parameters for acquiring the normalization data. For example, the computing system 160 may initialize parameters used in the analysis of the measurements. As an example, for reflectivity measurements, as illustrated in equation 2, the computing system 160 may initialize parameters, such as the dark signals for the measurement and normalization channel, e.g., I_{dark}(λ) and N_{dark}, and the most recent measurement and normalization reference data, e.g., I_{ref}(λ) and N_{ref}, and the reflectivity of the reference, e.g., R_{ref}(λ). The dark signals, e.g., I_{dark}(λ) and N_{dark}, may be acquired during calibration of the metrology device, while the most recent reference data, e.g., I_{ref}(λ) and N_{ref}, may be acquired from a reference sample using a data acquisition flow similar to that shown in FIG. 2. The computing system 160 may set the detector 130 to an external trigger mode, set the number of spectra to collect by the detector 130, the integration time (IT), a phase delay of the normalization channel 150, and may arm the detector 130 and the digitizer 158. The computing system 160 may further initialize the motion parameters of the stage 106 and provides a trigger to the stage 106 to move to a desired position.

At block 220, the stage 106 moves to the desired position and generates a stage trigger, e.g., to the detector 130, indicating that the stage 106 is in position and the detector 130 may begin the acquisition of measurement data.

At block 230, upon receiving the stage trigger, the detector 130 starts acquiring measurements from the sample 101. The detector 130 executes integration and sends a flash to the digitizer 158 (and optionally to the stage 106) to synchronize acquisition of the normalization data with the acquisition of the measurements. The detector 130 may send the flash to the digitizer 158 at every end of scan (EOS), at the end of a scan read out, or at a predetermined time after starting a scan. The stage 106 may prepare to scan in the vertical direction or move to a new desired position at block 220 in response to the flash.

At block 240, the digitizer 158 starts integration of the signal acquired by the normalization detector 152 in the normalization channel 150 in response to receiving the flash from the detector 130, thereby synchronizing acquisition of the normalization data with the acquisition of the measurements from detector 130. In some implementations, the digitizer 158 may delay the start of the integration time by a predetermined phase delay in order to align the time of acquisition of the normalization data with the time of acquisition of the measurements from the detector 130. As discussed above, if the normalization detector 152 is a photodetector, integration of the signal results in a single data value, e.g., normalized mean intensity. If the normalization detector 152 is a spectrometer, on the other hand, the integration of the signal results in a spectrum, e.g., normalized mean intensity per wavelength. The resulting normalization data is provided by the digitizer 158 to the computing system 160, e.g., via Ethernet.

At block 250, the computing system 160 retrieves the measurement data, e.g., spectra, from the detector 130 from block 230 and the normalization data from the normalization detector 152 from block 240. The computing system 160 may use the aligned normalization data to normalize the measurement data. In some implementations, the first spectrum from detector 130 and the last data value from the digitizer 158 may be removed to achieve proper synchronization. The computing system 160 may normalize the measurement data based on the normalization data. For example, as discussed above, the computing system 160 may subtract the dark signals, I_{dark}(λ), from the sample data and previously measured reference data, Iₛₐₘ (λ) and I_{ref}(λ), and may subtract the normalization channel dark signal, N_{dark}, from the sample normalization data and reference normalization data Nₛₐₘ and N_{ref}, and may normalize the measurement data using the normalization data as illustrated in equation 2.

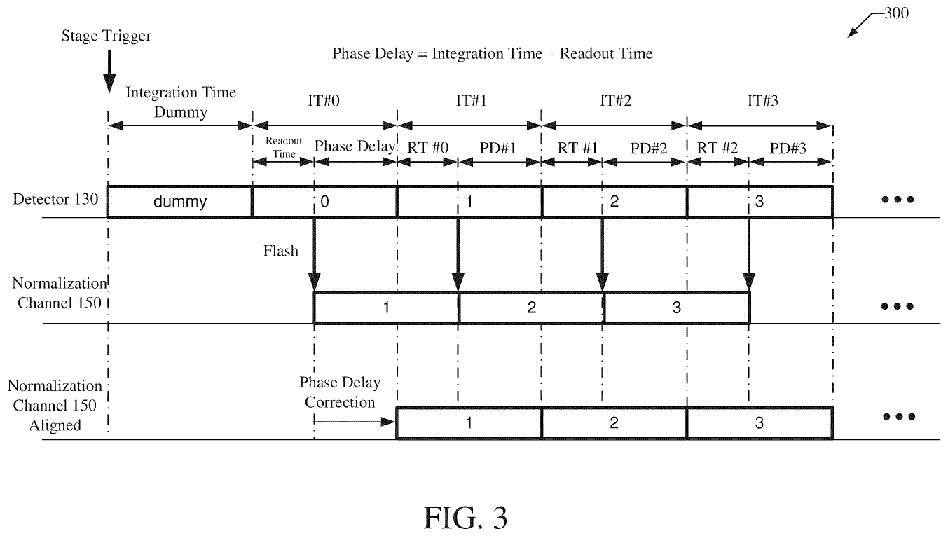

FIG. 3 illustrates a timing diagram 300 showing an example of the synchronization and alignment between the detector 130 and the normalization channel 150 during measurement and normalization data acquisition performed by metrology devices 100 and 100′ shown in FIGS. 1A and 1B and discussed in FIG. 2.

As illustrated, the synchronization between the normalization channel 150 and the measurement detector 130 may rely on the flash from the detector 130. For example, the flash may be produced by the detector 130 at the end of scan (EOS). The flash may be provided to the digitizer 158 of the normalization channel 150 from the detector 130 after a predetermined time after starting a scan, e.g., at the end of each readout period following the completion of each scan.

The timing diagram 300 illustrates the timing between the stage 106 and the detector 130. Before the stage trigger, the detector 130 and the normalization channel are in an armed state. The stage 106 sends the stage trigger to the detector 130. The detector 130 starts a burst acquisition after receiving the stage trigger during a dummy integration time. After the dummy integration time, the next integration time IT #0 begins and the dummy readout time begins. At the end of integration time IT #0, the next integration time IT #1 begins and the IT #0 readout time begins. The detector 130 may continue the process for the predetermined number N of scans, and the measurement data is provided to the computing system 160 and stored.

The timing diagram 300 further illustrates the timing between the detector 130 and the normalization channel 150, more specifically, the digitizer 158. After a predetermined time from starting an integration time, e.g., at the end of each readout time, the detector 130 sends a flash to the normalization channel. The total number of flashes (N) may be equal to the total number of scans. After arming, the normalization channel 150 is expecting N triggers. Once the N triggers are received, the first measurement cycle is completed. The time interval between two flashes from the detector is equal to the integration time (IT) for the normalization channel. The normalization channel 150 starts the integration after receiving the flash. Once the digitizer 158 is armed, the digitizer 158 may generate one normalization channel scan per flash until the total number of flashes is reached.

As illustrated in FIG. 3, by initiating the integration time IT upon receipt of the flash from the detector 130, the normalization data is synchronized with the measurement data acquired by the detector 130. As illustrated, the normalization channel 150 may be aligned by applying a phase delay (PD) correction after receiving the flash, so that the integration time for the normalization data occurs at the same time as the integration time of the measurement data by detector 130, i.e., the integration times for both the normalization channel 150 and the detector 130 begin and end at the same time. As illustrated, the detector 130 performs a dummy scan, after receiving the stage 106 trigger. The detector 130 does not export the dummy scan data to the computing system 160 (or the computing system 160 may disregard the dummy scan data), but the end of dummy scan enables the flash to the normalization channel 150. If no phase delay is applied, the scans for the normalization channel 150 start after the scans by the detector 130 and, consequently, the integration times for the normalization channel 150 will not be aligned with the integration times for the detector 130.

By applying the appropriate phase delay correction after receiving the flash, the first integration time for the normalization channel 150 is aligned with the IT #1 of the detector 130, i.e., the scans start at the same time, and subsequent scans are similarly aligned. Consequently, the integration times for the normalization channel 150 are aligned with the integration times for the detector 130. The appropriate phase delay, for example, may be the integration time (IT) minus the readout time for the detector 130. The readout time may include any physical delays in the communication with the detector 130, e.g., the time required for the trigger to be provided to the digitizer 158 from the detector 130 via the computing system 160, in addition to the readout time of the detector 130. The phase delay may vary if the integration time (IT) changes. The readout time may be different from one system to another, but it remains constant within a system even if the integration time varies. The readout time may be determined through calibration of the system.

As discussed above, in some implementations, the normalization channel 150 may generate normalization data that is a function of wavelength. In some implementations, for example, the normalization detector 152 may be a spectrometer that acquires normalization data that is a function of wavelength. In some implementations, the normalization detector 152 may be a photodetector that acquires a total intensity value for the full range of wavelengths, and the total intensity value may be scaled to generate normalization data that is a function of wavelength. For example, the scaling factor or weights for each wavelength may be predetermined during calibration. In these implementations, rather than normalizing the measurement data using a single value, a different weighting factor may be applied to each wavelength of the measurement data, e.g., the measurement data may be scaled using a curve rather than a constant value.

To determine the wavelength scaling factor for normalizing, by way of example, a normalized variance over mean (VOM(λ)), sometimes referred to as variance/mean ratio (VMR), may be acquired. The VOM(λ), for example, may be determined based on a plurality of scans, e.g., 500 scans, acquired by the normalization channel 150 from a reference sample. The acquired normalization data is a raw intensity as a function of wavelength N(λ). The VOM(λ) may be determined as:

$$VOM ( λ ) = \frac{var ( N ( λ ) )}{mean ( N ( λ ) )} \qquad eq . 3$$

where var(N(λ)) is the variance of the raw intensities N(λ) and mean (N(λ)) is the mean of the raw intensities N(λ) acquired by the normalization channel 150 from a reference sample. Additionally, a variance over mean is similarly determined in a shot noise limited region for the normalization detector 152, such as in an IR wavelength range of 900 nm to 1000 nm. The shot noise limited VOM_{IR}(λ) may be determined as:

$${VOM}_{IR} ( λ ) = \frac{var ( {N}_{IR} ( λ ) )}{mean ( {N}_{IR} ( λ ) )} \qquad eq . 4$$

where var(N_{IR}(λ)) is the variance and mean (N_{IR}(λ)) is the mean of the raw intensities N_{IR}(λ) acquired by the normalization channel 150 over the shot noise limited region from a reference sample. The normalized variance over mean VOM_{IR,N}(λ) is generated by dividing the variance over mean VOM(λ) by the shot noise limited variance over mean VOM_{IR}(λ), e.g.,

$${VOM}_{IR , N} ( λ ) = \frac{VOM ( λ )}{mean ( {VOM}_{IR} ( λ ) )} \qquad eq . 5$$

A curve fit or a smoothing function may be applied and the wavelength scaling factor f(λ) may be determined, e.g., based on the square root of the absolute value of the normalized variance of mean and subtracting 1, e.g.,

$$f ( λ ) = \sqrt{\vert {VOM}_{IR , N} ( λ ) \vert} - 1 \qquad eq . 6$$

The wavelength scaling factor f(λ) may then be applied to the measurement data acquired by the detector 130. For example, if the metrology device 100 is performing reflectometry measurements, the normalized reflectance from the sample R_{s,n} may be determined as:

$${R}_{s , n} ( λ ) = \frac{\hat{{I}_{s}} ( λ ) - \hat{{I}_{b}} ( λ )}{\hat{{I}_{r}} ( λ ) - \hat{{I}_{b}} ( λ )} {R}_{r} ( λ ) \qquad eq . 7$$

$$\hat{{I}_{x}} ( λ ) = {I}_{x} ( λ ) - {I}_{d} ( λ ) \qquad eq . 8$$

Where Iₛ is the signal intensity from the sample, I_{b} is the background signal intensity, Iᵣ is the signal intensity from the reference, Rᵣ is the reflectance of the reference, subscript x represents any of s, b, d, or r, and I_{d} is the dark signal intensity. With normalization, each [symbol] (λ) term becomes:

$$\hat{{I}_{x}} ( λ ) = \frac{\hat{{I}_{x}} ( λ )}{1 + ( \frac{\hat{N} ( λ )}{\hat{{N}_{0}} ( λ )} - 1 ) f ( λ )} \qquad eq . 9$$

Where \vec{N}(λ) is the normalization data acquired by the normalization channel 150 and [symbol] (λ) is the mean value of the normalization data. Equation 9 may be re-written with the dark correction as:

$${I}_{x} ( λ ) - {I}_{d} ( λ ) = \frac{{I}_{x} ( λ ) - {I}_{d} ( λ )}{1 + ( \frac{N - {N}_{d}}{{N}_{0} - {N}_{d}} - 1 ) f ( λ )} . \qquad eq . 10$$

Additionally, in some implementations, different gain values may be used with the normalization channel 150 for different modes to avoid saturation of the normalization detector 152 in the normalization channel 150 when switching between modes of operation of the metrology device. For example, if the metrology device 100 uses a high intensity light source, e.g., during a video acquisition state, the normalization detector 152 may saturate. When transitioning from a saturated to non-saturated state, the normalization detector 152 requires time to stabilize, e.g., approximately 100 ms or more.

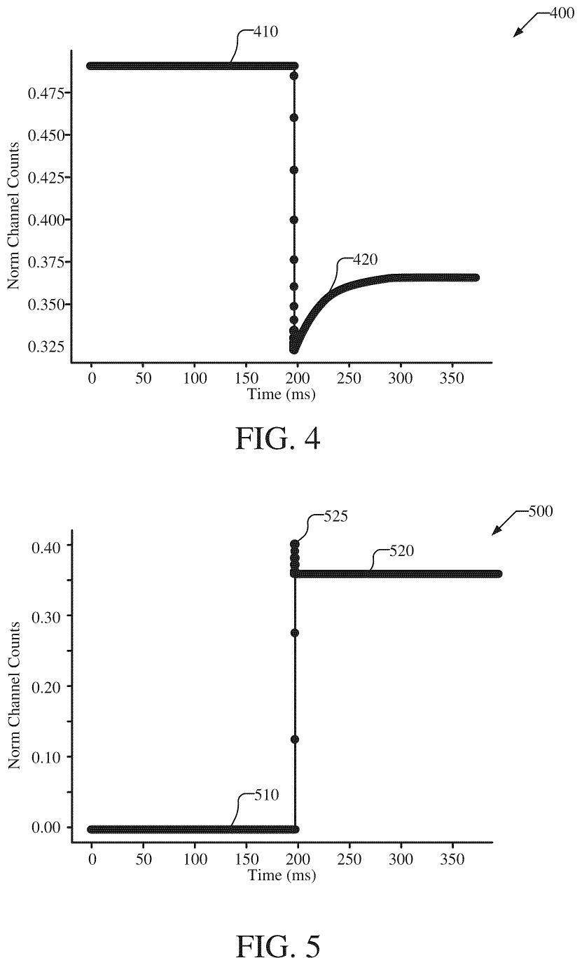

FIG. 4, by way of example, illustrates a graph 400 showing saturation of the normalization channel and the time required to recover from saturation. As illustrated at line 410, the normalization detector 152 in the normalization channel 150 is saturated, e.g., during a video focus state. At time 200 ms, the metrology device 100 may switch modes, e.g., to a measurement state. As illustrated by line 420, a significant amount of time, e.g., 100 ms, may be required for the normalization detector 152 to recover from saturation, resulting in poor signal integrity and stability during the saturation recovery period.

To avoid saturation of the normalization detector 152 while in different modes, such as a video focus state, different gains may be applied to the normalization detector 152 for the different states. The gain switching may be triggered based on when the metrology device 100 switches modes. For example, in some implementations, the gain switching may be triggered by mirror movement into the optical path of the light to switch between modes. For example, when switching between a video to a measurement state, a UV mirror may be moved out of the optical path, after which the gain of the normalization detector 152 may be switched to the measurement-specific gain. Conversely, when switching between the measurement to the video state, the gain of the normalization detector 152 is first switched to the video gain, then the UV mirror may be moved into the optical path.

FIG. 5, by way of example, illustrates a graph 500 showing the absence of saturation of the normalization detector 152 due to gain switching when the metrology device 100 switches modes. As illustrated at line 510, for example, a video-specific gain may be applied to the normalization detector 152 while the metrology device 100 is in a video focus state. At time 200 ms, the metrology device 100 may switch modes, e.g., to a measurement state and a measurement-specific gain is applied to the normalization detector 152 at line 520. As illustrated by peak 525, the normalization channel is quickly stabilized, e.g., in less than 3 ms.

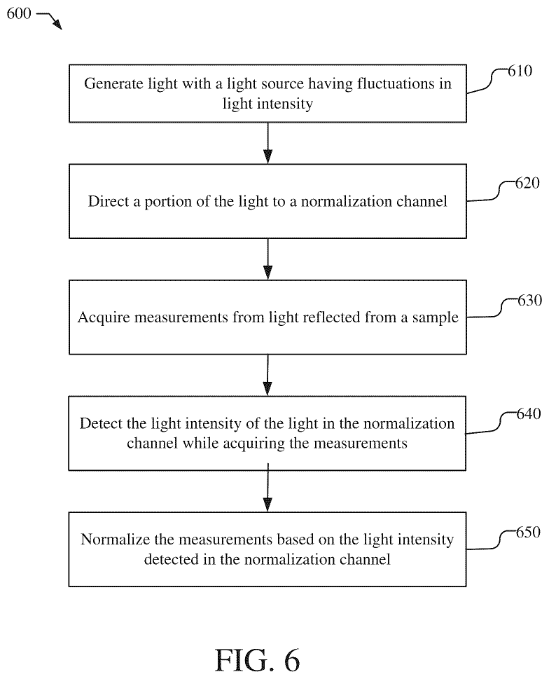

FIG. 6 shows an illustrative flowchart depicting an example method 600 for performing optical metrology that mitigates light source noise using a normalization channel, as discussed herein. In some implementations, the example method 600 may be performed by a metrology device, such as a metrology device 100 or 100′ illustrated in FIGS. 1A and 1B, respectively.

As illustrated in FIG. 6, the method includes generating light with a light source having fluctuations in light intensity (610), e.g., as illustrated and discussed in relation to light source 110, in FIGS. 1A and 1B. For example, the light may be produced by a light source, multiple lasers, or LEDs, etc.

A portion of the light is directed to a normalization channel (620), e.g., as illustrated by beam splitter 120 and 122 in FIGS. 1A and 1B, respectively. In some implementations, the light is normally incident on the sample, and directing the portion of the light to a normalization channel includes splitting the light with a beam splitter that directs a first portion of the light to the sample, and directs a second portion of the light to the normalization channel, the beam splitter further directs light reflected from the sample to a detector for acquiring the measurements, e.g., as illustrated by beam splitter 120 in FIG. 1A. In some implementations, the light is obliquely incident on the sample, and directing the portion of the light to a normalization channel includes splitting the light with a beam splitter that directs a first portion of the light to the normalization channel, and directs a second portion of the light to the sample or to a detector for acquiring the measurements from light reflected from the sample, e.g., as illustrated by beam splitter 122 in FIG. 1B.

Measurements from the light reflected from a sample are acquired (630), e.g., as illustrated and discussed in relation to detector 130 in FIGS. 1A and 1B, and block 230 in FIG. 2.

The light intensity of the light in the normalization channel is detected while acquiring the measurements (640), e.g., as illustrated and discussed in relation to normalization channel 150 in FIGS. 1A and 1B, and block 240 in FIG. 2.

The measurements are normalized based on the light intensity detected in the normalization channel (650), e.g., as illustrated and discussed in relation to normalization channel 150 and computing system 160 in FIGS. 1A and 1B, and block 250 in FIG. 2.

In some implementations, the measurements may be acquired from light reflected from the sample by collecting a plurality of separate measurements and the method may further include synchronizing detection of the light intensity of the light in the normalization channel with the separate measurements, e.g., as illustrated and discussed in relation to the flash trigger pulse and the measurement data scans performed by the detector 130 and the normalization channel scans performed by the normalization channel 150 in FIG. 3.

In some implementations, the method may further include aligning the light intensity detected in the normalization channel with the measurements, e.g., as illustrated and discussed in relation to the measurement data scans performed by the detector 130 and the normalization channel scans performed by the normalization channel 150 in FIG. 3. For example, in some examples, a phase delay may be applied to the detection of the light intensity in the normalization channel, e.g., as illustrated and discussed in relation to the phase delay and the measurement data scans performed by the detector 130 and the normalization channel scans performed by the normalization channel 150 in FIG. 3.

In some implementations, the light intensity of the light in the normalization channel is detected by collecting a plurality of samples of the light intensity while acquiring the measurements and combining the plurality of samples of the light intensity, e.g., as illustrated and discussed in relation to integration of the light in the normalization channel in FIGS. 1A and 1B, block 240 of FIG. 2, and in FIG. 3.

In some implementations, the light is broadband light and the measurements are spectral measurements. The light intensity of the broadband light in the normalization channel is detected while acquiring the spectral measurements by determining a total intensity of the light source, and normalizing the spectral measurements based on the light intensity detected in the normalization channel includes applying the total intensity of the light source to all wavelengths in the spectral measurements, e.g., as illustrated and discussed in relation to normalization channel 150 in FIGS. 1A and 1B, and block 240 in FIG. 2, and equation 2. In some implementations, the light intensity of the broadband light in the normalization channel is detected while acquiring the spectral measurements by detecting an intensity for different wavelengths in the broadband light, and normalizing the spectral measurements based on the light intensity detected in the normalization channel applying the intensity for different wavelengths to corresponding wavelengths in the spectral measurements, e.g., as illustrated and discussed in relation to normalization channel 150 in FIGS. 1A and 1B, and block 240 in FIG. 2, and equations 7, 9, and 10.

The above description is intended to be illustrative, and not restrictive. For example, the above-described examples (or one or more aspects thereof) may be used in combination with each other. Other implementations can be used, such as by one of ordinary skill in the art upon reviewing the above description. Also, various features may be grouped together and less than all features of a particular disclosed implementation may be used. Thus, the following aspects are hereby incorporated into the above description as examples or implementations, with each aspect standing on its own as a separate implementation, and it is contemplated that such implementations can be combined with each other in various combinations or permutations. Therefore, the spirit and scope of the appended claims should not be limited to the foregoing description.

What is claimed is:

1. A method for performing optical metrology that mitigates light source noise using a normalization channel, comprising:
generating light with a light source having fluctuations in light intensity;
directing a portion of the light to a normalization channel;
acquiring measurements from light reflected from a sample;
detecting the light intensity of the light in the normalization channel while acquiring the measurements; and
normalizing the spectral measurements based on the light intensity detected in the normalization channel.

2. The method of claim 1, wherein acquiring measurements from light reflected from the sample comprises collecting a plurality of separate measurements, the method further comprising synchronizing detection of the light intensity of the light in the normalization channel with the separate measurements.

3. The method of claim 1, the method further comprising aligning the light intensity detected in the normalization channel with the measurements.

4. The method of claim 3, wherein aligning the light intensity detected in the normalization channel with the measurements comprises applying a phase delay to the detection of the light intensity in the normalization channel.

5. The method of claim 1, wherein detecting the light intensity of the light in the normalization channel comprises:
collecting a plurality of samples of the light intensity while acquiring the measurements; and
combining the plurality of samples of the light intensity.

6. The method of claim 1, wherein the light is broadband light and the measurements are spectral measurements.

7. The method of claim 6, wherein detecting the light intensity of the broadband light in the normalization channel while acquiring the spectral measurements comprises determining a total intensity of the light source, and wherein normalizing the spectral measurements based on the light intensity detected in the normalization channel comprises applying the total intensity of the light source to all wavelengths in the spectral measurements.

8. The method of claim 6, wherein detecting the light intensity of the broadband light in the normalization channel while acquiring the spectral measurements comprises detecting an intensity for different wavelengths in the broadband light, and wherein normalizing the spectral measurements based on the light intensity detected in the normalization channel comprises applying the intensity for different wavelengths to corresponding wavelengths in the spectral measurements.

9. The method of claim 1, wherein the light is normally incident on the sample, and wherein directing the portion of the light to a normalization channel comprises splitting the light with a beam splitter that directs a first portion of the light to the sample, and directs a second portion of the light to the normalization channel, the beam splitter further directs light reflected from the sample to a detector for acquiring the measurements.

10. The method of claim 1, wherein the light is obliquely incident on the sample, wherein directing the portion of the light to a normalization channel comprises splitting the light with a beam splitter that directs a first portion of the light to the normalization channel, and directs a second portion of the light to the sample or to a detector for acquiring the spectral measurements from light reflected from the sample.

11. A metrology device configured for performing optical metrology that mitigates light source noise using a normalization channel, comprising:
a light source generating light having fluctuations in light intensity;
a beam splitter that directs a portion of the light to a normalization channel;
a detector configured to acquire measurements from light reflected from a sample;
a normalization channel configured to detect the light intensity of the light while acquiring the measurements; and
a computing system configured for normalizing the measurements based on the light intensity detected in the normalization channel.

12. The metrology device of claim 11, wherein the detector is configured to acquire measurements from light reflected from the sample by collecting a plurality of separate measurements, the normalization channel is further configured to synchronize detection of the light intensity of the light in the normalization channel with the separate measurements.

13. The metrology device of claim 11, wherein the normalization channel is further configured to align the light intensity detected in the normalization channel with the measurements.

14. The metrology device of claim 13, wherein the normalization channel is further configured to align the light intensity detected in the normalization channel with the measurements by applying a phase delay to the detection of the light intensity in the normalization channel.

15. The metrology device of claim 11, wherein the detector is configured to detect the light intensity of the light in the normalization channel by being configured to:
collect a plurality of samples of the light intensity while acquiring the measurements; and
combine the plurality of samples of the light intensity.

16. The metrology device of claim 11, wherein the light is broadband light and the measurements are spectral measurements.

17. The metrology device of claim 16, wherein the normalization channel is configured to detect the light intensity of the broadband light in the normalization channel while acquiring the spectral measurements by being configured to determine a total intensity of the light source, and the computing system normalizes the spectral measurements based on the light intensity detected in the normalization channel by applying the total intensity of the light source to all wavelengths in the spectral measurements.

18. The metrology device of claim 16, wherein the normalization channel is configured to detect the light intensity of the broadband light in the normalization channel while acquiring the spectral measurements by being configured to detect an intensity for different wavelengths in the broadband light, and the computing system normalizes the spectral measurements based on the light intensity detected in the normalization channel by applying the intensity for different wavelengths to corresponding wavelengths in the spectral measurements.

19. The metrology device of claim 11, wherein the light is normally incident on the sample, and the beam splitter is configured to directs a first portion of the light to the sample, and direct a second portion of the light to the normalization channel, and further direct light reflected from the sample to the detector for acquiring the spectral measurements.

20. The metrology device of claim 11, wherein the light is obliquely incident on the sample, and the beam splitter is configured to direct a first portion of the light to the normalization channel, and direct a second portion of the light to the sample or to the detector for acquiring the spectral measurements from light reflected from the sample.
